(19) United States
(12) Patent Application Publication
(10) Pub. No.: US 2006/0017111 A1
(43) Pub. Date: Jan. 26, 2006

(54) Semiconductor device and method of fabricating the same

(75) Inventors: Eiji Kamiya, Yokkaichi (JP); Hiroaki Hazama, Yokkaichi (JP); Tooru Hara, Yokkaichi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/186,896

(22) Filed: Jul. 22, 2005

(30) Foreign Application Priority Data
Jul. 23, 2004 (JP) 2004-215852

(51) Int. Cl. H01L 29/94; H01L 23/52

(52) U.S. Cl. 257/368; 257/758

(57) ABSTRACT

A semiconductor device includes a semiconductor substrate, a gate insulating film formed on the semiconductor substrate, a gate electrode formed on the gate insulating film, an interlayer insulating film formed so that the gate electrode is buried therein, a contact hole formed in the interlayer insulating film so as to be adjacent to the gate electrode, the contact hole having a sidewall, a nitride film for the spacer formed on the sidewall of the contact hole and having a lower end, an insulating film interposed between the lower end of the spacer nitride film and a surface of the semiconductor substrate, and a conductor layer for the electrode formed so as to fill the contact hole.

### CROSS-REFERENCE TO RELATED APPLICATIONS

This application is based upon and claims the benefit of priority from the prior Japanese Patent Application No. 2004-215852, filed on Jul. 23, 2004, the entire contents of which are incorporated herein by reference.

### BACKGROUND OF THE INVENTION

1. Field of the Invention

The present invention relates to a semiconductor device having gate electrodes and contact holes adjacent to the gate electrodes and a method of fabricating the semiconductor device.

2. Description of the Related Art

Some types of semiconductor devices such as NAND flash memories employ a gate performing process and the following process of forming contacts between gate electrodes. A thin thermal oxide film is formed after a gate structure has been formed. Also, another oxide film is formed after formation of the gate structure for the purpose of improvement in reliability. Thereafter, a silicon nitride film is formed for forming sidewalls. After execution of an ion implantation process, a silicon nitride film is again formed as a stopper in a chemical mechanical polishing (CMP). Successively, an interlayer insulating film is deposited so that gate electrodes are buried therein, and the CMP process is carried out to flatten the interlayer insulating film (planarization). Subsequently, the interlayer insulating film, silicon nitride film, silicon oxide film and the like are etched so that a surface of the silicon substrate is exposed, whereby contact holes are formed. An electrical material and the like are buried in the contact holes. JP-A-2002-110822 discloses the foregoing technique, for example.

Particularly in NAND flash memories, short circuit failure tends to occur between contacts with finer design rule. In view of the aforementioned drawback, a spacer such as a silicon nitride film is formed on side walls of the contact hole after the forming of the contact holes for the purpose of improvement in improvement in the insulation performance and reliability. JP-A-2002-222932 discloses the aforementioned technique, for example.

In a process of providing the spacers, contact holes are formed and thereafter, a silicon nitride film is formed. Subsequently, spacers are formed by a reactive ion etching (RIE) process, whereby the silicon nitride film on the bottoms of the contact holes is exposed.

When a configuration of providing the spacers is employed, the silicon nitride film as the spacers is formed with the contact holes being present. Accordingly, the silicon substrate is partially in contact with the silicon nitride film when the silicon nitride film is formed on the bottom of each contact hole. Such contact with the silicon nitride film causes stress in the silicon substrate. The stress results in crystal defects or traps of the gate oxide film.

Furthermore, in forming the contact holes, the interlayer insulating film first needs to be etched by the RIE process in one chamber and thereafter, the silicon nitride film needs to be etched in another chamber. Thus, the RIE process needs to be carried out twice in the contact hole forming process, and additionally, the forming of spacers requires further another RIE process. Consequently, since the number of execution times of the RIE process is increased, the number of processing steps and the number of processes are increased and accordingly, the costs are increased.

### BRIEF SUMMARY OF THE INVENTION

Therefore, an object of the present invention is to provide a semiconductor device in which the spacer can be prevented from contact with the semiconductor substrate even in employment of spacers, thereby improving reliability and moreover, the number of execution times of the RIE process can be reduced, and a method of fabricating the semiconductor device.

The present invention provides a semiconductor device comprising a semiconductor substrate, a gate insulating film formed on the semiconductor substrate, a gate electrode formed on the gate insulating film, an interlayer insulating film formed so that the gate electrode is buried therein, a contact hole formed in the interlayer insulating film so as to be adjacent to the gate electrode, the contact hole having a sidewall, a nitride film for the spacer formed on the sidewall of the contact hole and having a lower end, an insulating film interposed between the lower end of the spacer nitride film and a surface of the semiconductor substrate and a conductor layer for the electrode formed so as to fill the contact hole.

The invention also provides a method of fabricating a semiconductor device comprising forming a gate electrode on a semiconductor substrate, forming an insulating film and a nitride film so as both to cover the gate electrode, forming an interlayer insulating film, processing the interlayer insulating film by an RIE process, thereby forming a contact hole so that the insulating film and the nitride film remains on a bottom of the contact hole, forming a nitride film for a spacer in the contact hole, processing the spacer nitride film, the nitride film and the insulating film by an RIE process so that a surface of the semiconductor device is exposed, and burying a conductive layer for an electrode in the formed contact hole.

### BRIEF DESCRIPTION OF THE DRAWINGS

Other objects, features and advantages of the present invention will become clear upon reviewing the following description of the embodiment with reference to the accompanying drawings, in which:

FIGS. 1A and 1B are schematic sectional views of a contact hole formed in the semiconductor device in accordance with one embodiment of the present invention;

FIGS. 2A to 2V are schematic sectional views of the semiconductor device, showing phases of the fabrication process;

FIGS. 3A and 3B are views similar to FIGS. 1A and 2A, showing a second embodiment of the invention, respectively; and

FIGS. 4A to 4R are schematic sectional views of the semiconductor device, showing phases of the fabrication process.

### DETAILED DESCRIPTION OF THE INVENTION

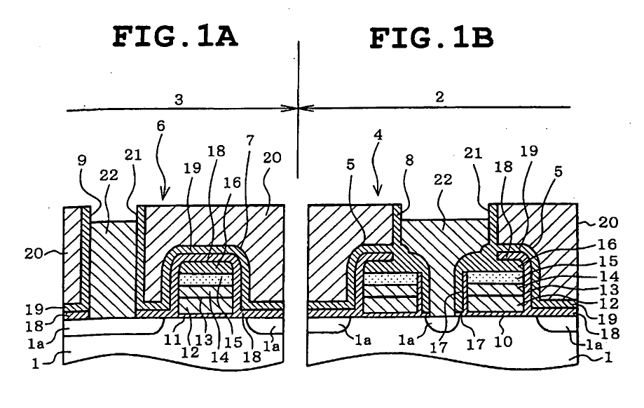

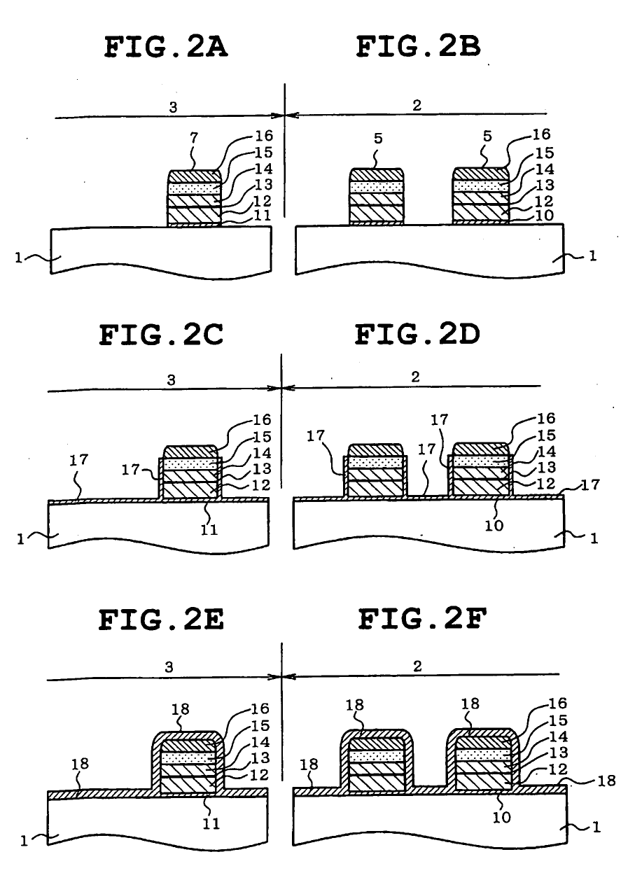

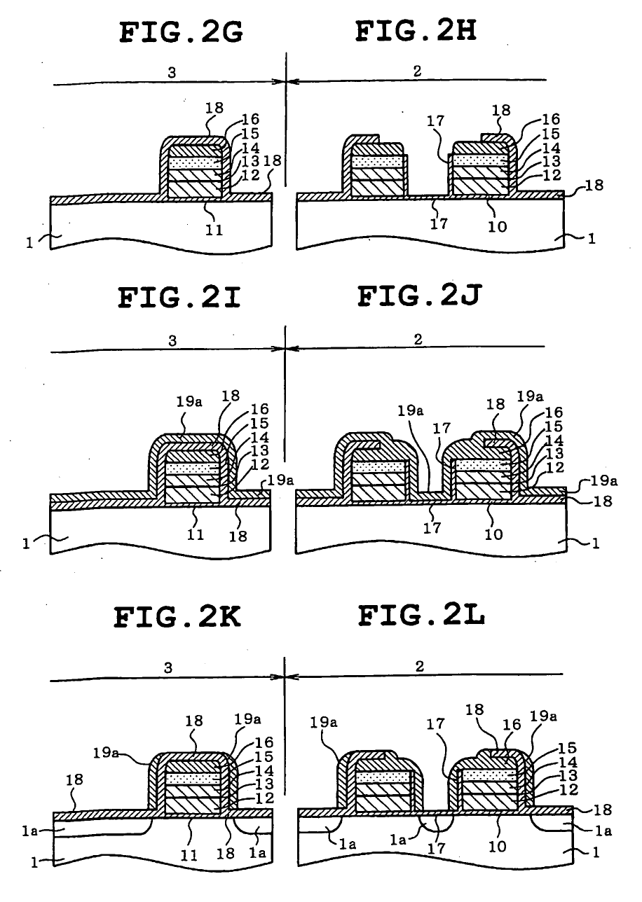

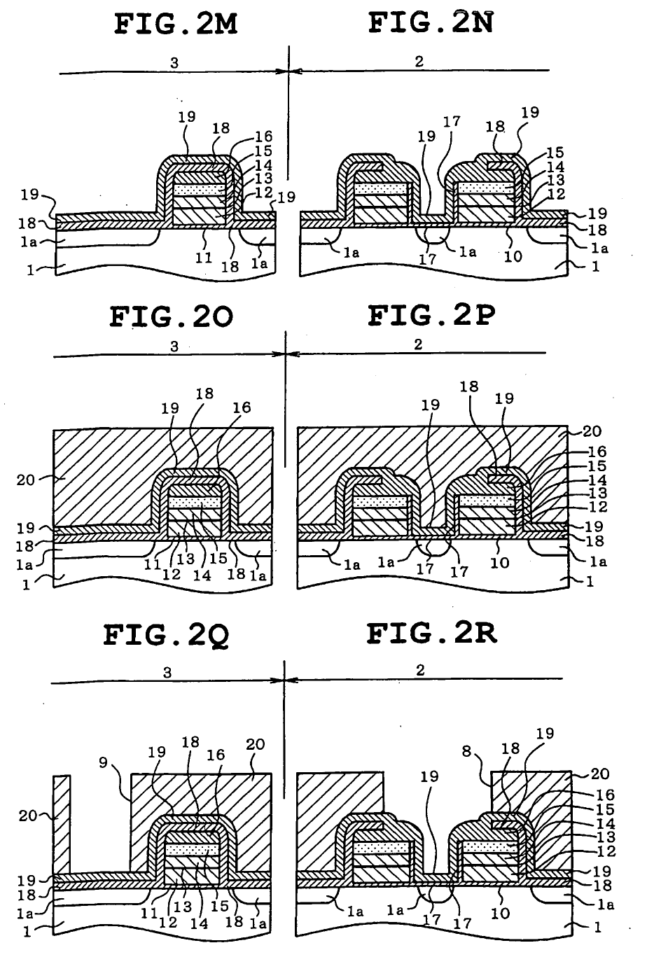

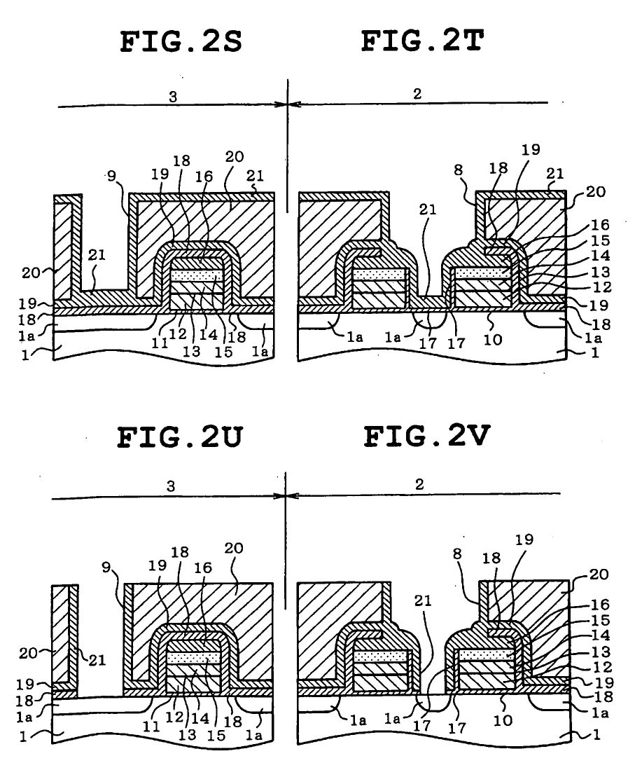

An embodiment of the present invention will be described with reference to FIGS. 1A to 2V. The invention is applied to a NAND flash memory in the embodiment.

The NAND flash memory includes a silicon substrate 1 serving as a semiconductor substrate, a memory cell region 2 and a peripheral circuit region 3 both formed on the silicon substrate 1. A number of memory cell transistors and selective transistors are formed in the memory cell region 2. High or low breakdown voltage transistors for operating the memory transistors and the like are formed in the peripheral circuit region 3.

FIG. 1A shows a gate electrode 5 of the selective gate transistor 4 formed in the memory cell region 2, whereas FIG. 1B shows a gate electrode 7 of the high breakdown voltage transistor 6 formed in the peripheral circuit region 3. Two contact holes 8 and 9 are formed in the memory cell and peripheral circuit regions 2 and 3 respectively. In this case, the contact hole 8 is formed between the gate electrodes 5 by a self-alignment technique. The shown section is taken along a direction of an active area of the silicon substrate 1. Elements are isolated in active areas adjacent to each other by shallow trench isolation (STI).

An impurity diffusion region 1a is formed on the silicon substrate 1 so as to correspond to an active area of the high breakdown voltage transistor 6 as shown in FIGS. 1A and 1B. The impurity diffusion region 1a serves as a source-drain region. Gate oxide films 10 and 11 are also formed on the silicon substrate 1 so as to correspond to the gate electrodes 5 and 7 respectively. The gate oxide films 10 and 11 serve as gate insulating films and have film thicknesses corresponding to breakdown voltages respectively. The gate electrodes 5 and 7 are formed by stacking, from below, a polycrystalline silicon film 12 serving as a floating gate, an oxide-nitride-oxide (ONO) film 13, a polycrystalline silicon film 14 serving as a control gate, a tungsten silicide (WSi) film 15 and a silicon nitride film 16 sequentially.

A thin silicon oxide film 17 is formed by thermal oxidation on both sides of the gate electrodes 5 and 7 and a part of the surface of the silicon substrate 1 around the gate electrodes 5 and 7. A silicon oxide film 18 is formed on an upper surface of the silicon oxide film 17 so as to cover the gate electrodes 5 and 7. The silicon oxide film 18 extends over the entire surface of the silicon substrate 1. FIG. 1B shows the silicon oxide films 17 symmetrically formed on the gate electrodes respectively and only the silicon oxide films 18 formed at outer sides opposed to the inner silicon oxide films 17 respectively. Thus, each silicon oxide film 17 formed on the side of the silicon oxide film 18 is eliminated. However, both silicon oxide films 17 and 18 are formed on the outer side as shown in FIGS. 2C and 2D.

A silicon nitride film 19 is formed on upper surfaces of the silicon oxide films 17 and 18. The silicon oxide film 18 includes a part which is located between the gate electrodes 5 in the memory cell region 2 and is removed. The aforementioned thin silicon oxide film 17 remains on the removed part of the silicon oxide film 18. Consequently, the silicon nitride film 19 is in contact with the silicon nitride film 16 of the gate electrode 5.

An interlayer insulating film 20 is formed on the silicon nitride films 16 and 19 so as to fill up recesses resulting from formation of the gate electrodes 5 and 7 thereby to planarize the upper surface side of the silicon substrate 1. The planarization is carried out by a chemical mechanical polishing (CMP) process as will be described later. Parts of the interlayer insulating film 20 located between the gate electrodes 5 and near the gate electrode 7 are processed so that the silicon substrate 1 is exposed, whereupon contact holes 8 and 9 are formed. A silicon nitride film 21 serving as a spacer nitride film is formed on sidewalls of the contact holes 8 and 9. Polycrystalline silicon films 22 serving as electrode conductors are formed in the contact holes 8 and 9 respectively.

In the above-described structure, an insulation characteristic is improved by the silicon nitride film 21 formed on the sidewalls of the contact holes 8 and 9. The silicon nitride film 21 has a lower end in contact via the silicon oxide film 17 with the silicon substrate 1. Thus, since the silicon nitride film 21 is not in direct contact with the silicon substrate 1, the silicon substrate 1 can be prevented from being adversely affected and the reliability of the device can be improved.

The fabrication process of the foregoing structure will be described with reference to FIGS. 2A to 2V. The NAND flash memory as shown in FIGS. 1A and 1B is fabricated by the gate performing process has a plurality of gate oxide film regions using a gate electrode with a silicide structure and is fabricated by application of an etched gate process. In the gate performing process, firstly, a gate electrode structure is formed on the silicon substrate 1. More specifically, the silicon oxide films 10 and 11 are formed as the gate insulating films on the silicon substrate 1. The silicon oxide film 10 is used for memory cell transistors and has a film thickness of about 8 nm, for example. The silicon oxide film 11 is used for high breakdown voltage transistors and has a film thickness of about 40 nm, for example.

Subsequently, the gate electrodes 5 and 7 as shown in FIGS. 2A and 2B are obtained through a process in which elements are isolated by the STI. The gate electrodes 5 and 7 are formed by stacking, the polycrystalline silicon film 12 serving as the floating gate, the oxide-nitride-oxide (ONO) film 13, the polycrystalline silicon film 14 serving as the control gate, the tungsten silicide (WSi) film 15 and the silicon nitride film 16 sequentially.

Subsequently, the thin silicon oxide films 17 are formed on the sidewalls of the gate electrodes 5 and 7 and the surface of the silicon substrate 1 by the thermal oxidation process as shown in FIGS. 2C and 2D. Successively, the silicon oxide film 18 which is necessary to ensure the reliability of the device is formed by the chemical vapor deposition (CVD).

Next, as shown in FIGS. 2G and 2H, a photolithography process is carried out in order that part of the silicon oxide film 18 corresponding to the contact hole 8 to be formed in the memory cell region 2. In forming the contact hole 8 by the self-aligned contact, the silicon nitride film 19 serving as a stopper is sometimes damaged during the forming of the contact hole 8 of the interlayer insulating film 20, whereupon holes are formed in the silicon nitride film 19. The aforesaid photolithography is carried out to prevent damage due to etching through the silicon oxide film 18.

In the aforesaid process, photoresist (not shown) is coated and patterned so that a part thereof corresponding to the contact hole 8 is open. The silicon oxide film 18 is then etched. The silicon oxide film 18 is etched more easily than the silicon oxide film 17 formed by thermal oxidation since the silicon oxide film 18 is formed by the CVD. Accordingly, the silicon oxide film 18 is etched by a wet process under the condition where the silicon oxide film 17 formed thereunder is prevented from being peeled off. Consequently, the silicon oxide film 18 is partially removed while the silicon oxide film 17 remains unpeeled, as shown in FIGS. 2G and 2H.

Next, a silicon nitride film 19a is formed for sidewall processing as shown in FIGS. 2I and 2J. The sidewall processing is carried out so that spacers are formed on the sidewalls of the gate electrodes 5 and 7. Successively, a photolithography process is carried out so that an active layer of the high breakdown voltage transistor 6 is doped with impurities through the silicon oxide film 18, whereby the source-drain region 1a is formed.

Successively, the silicon nitride film 19 is again formed substantially over the entire upper surface side of the silicon substrate 1 as shown in FIGS. 2M and 2N. The silicon nitride film 19 is to serve as a stopper when the contact holes 8 and 9 are formed, as will be described later. The interlayer insulating film 20 is then deposited substantially over the entire upper surface side of the silicon substrate 1 so that the gate electrodes 5 and 7 are buried therein, as shown in FIGS. 2O and 2P. Subsequently, the interlayer insulating film 20 is planarized by the CMP process.

Next, a resist pattern of contact is formed by the photolithography process and thereafter, the contact holes 8 and 9 are formed by the RIE process, as shown in FIGS. 2Q and 2R. In this case, the etching progress is stopped at the surface of the silicon nitride film 19 and the silicon substrate 1 is not exposed, which process differs from conventional methods and processes. The resist is then removed.

Subsequently, the silicon nitride film 21 is formed as shown in FIGS. 2S and 2T. The silicon nitride film 21 is a nitride film for a spacer and serves as a material for sidewalls of the contacts. Thereafter, the silicon nitride film 21 and the silicon oxide film 18 are etched so that the silicon substrate 1 is exposed, as shown in FIGS. 2U and 2V. In this state, the silicon nitride film 21 remains on the sidewalls of the contact holes 8 and 9 of the interlayer insulating film 20. Successively, the polycrystalline silicon film 22 serving as a buried material and the like are deposited and an etchback process is carried out so that the structure as shown in FIGS. 1A and 1B is obtained. The processing of the contacts is completed.

The flash memory of the embodiment is fabricated through the above-described fabrication process. Accordingly, the silicon nitride film 21 formed on the sidewalls of the contact holes 8 and 9 has no portion in contact with the silicon substrate 1 and is accordingly formed with the silicon oxide films 17 and 18 being interposed between the silicon nitride film 21 and the substrate 1. Consequently, stress on the silicon substrate 1 can be relaxed or eased and electron trap of the gate oxide film can be reduced, whereupon a flash memory with high reliability can be achieved.

Furthermore, in the above-described fabrication process, the number of times of the etching process of the silicon nitride films 19a and 19 by the RIE process can be reduced to 2 although the etching process is conventionally carried out three times. Thus, the number of steps can be reduced such that the fabrication process can be shortened and the production cost can be reduced.

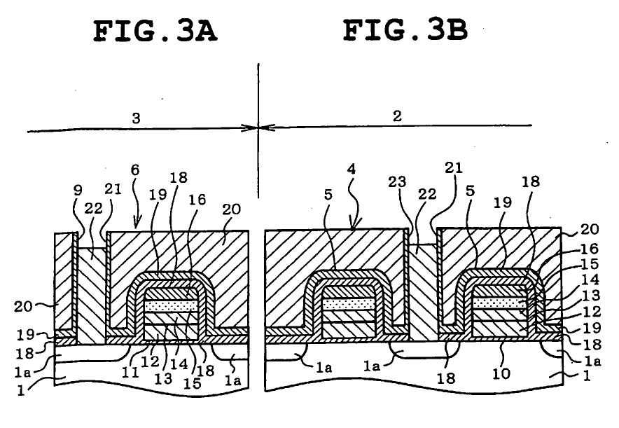

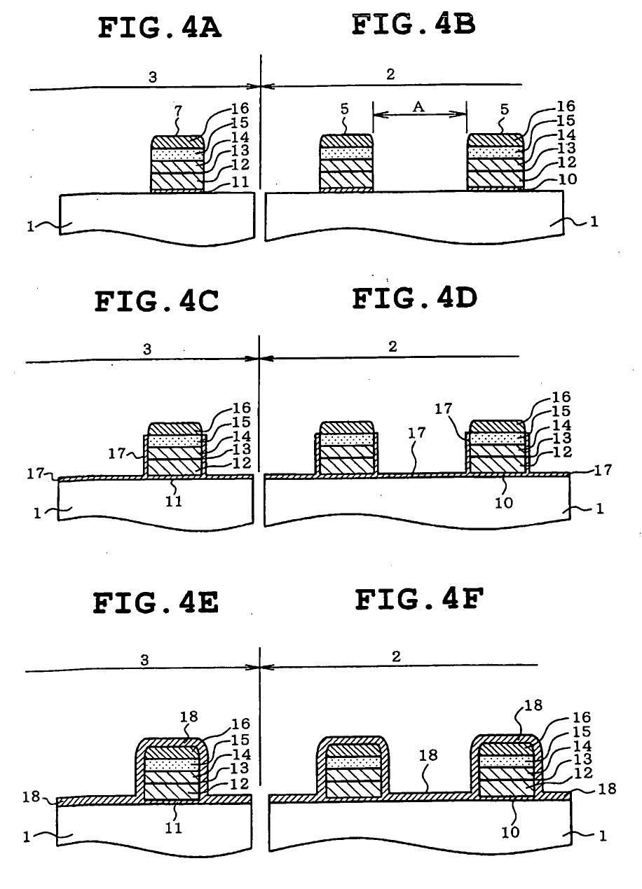

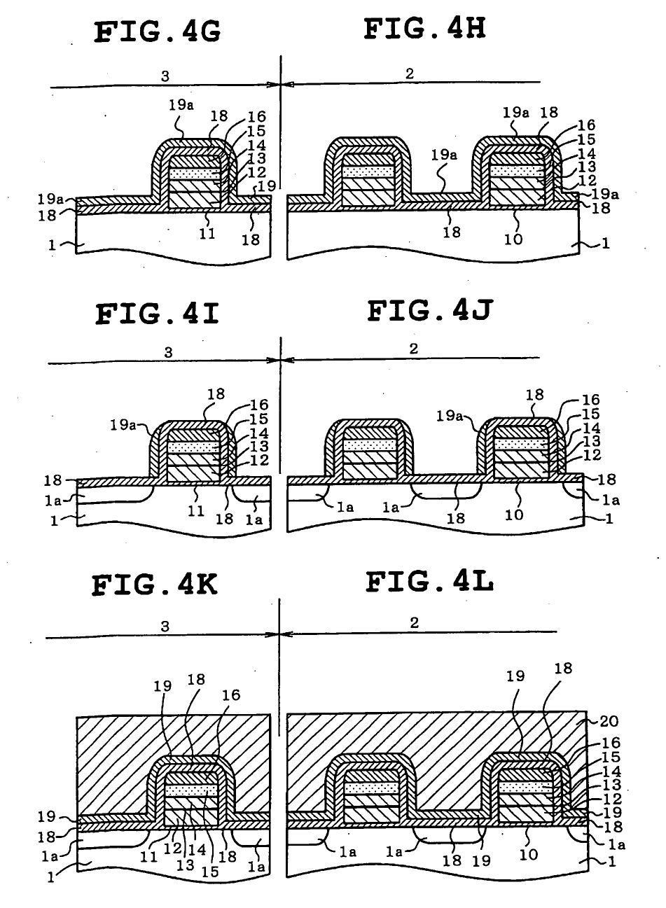

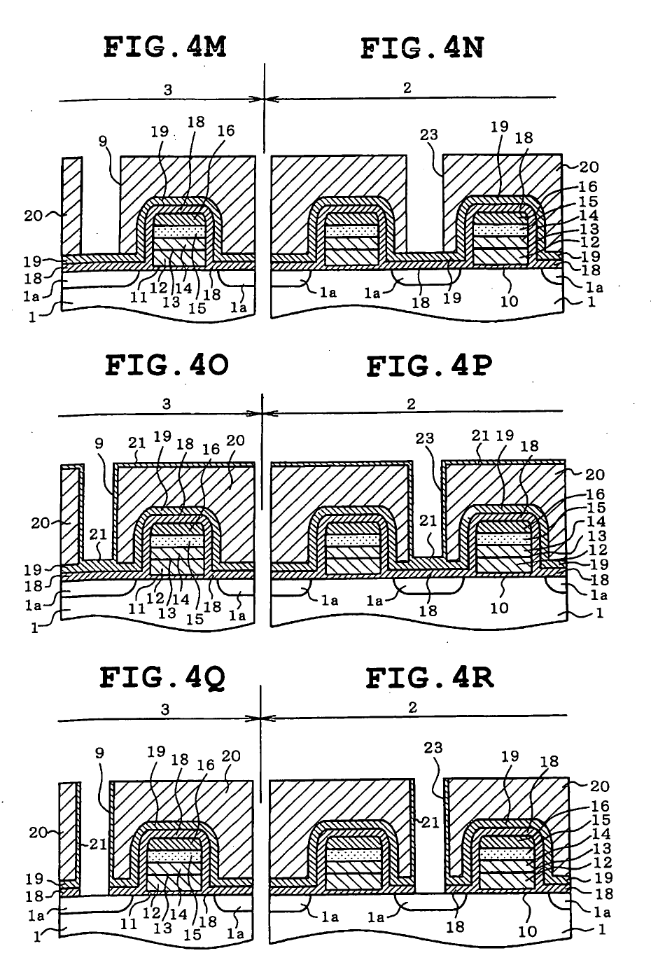

FIGS. 3A to 4R illustrate a second embodiment of the invention. The second embodiment differs from the first embodiment in the contact hole formed in a selective gate section of the memory cell region 2. The self-aligned contact hole 8 is used as such a contact hole in the first embodiment, whereas a non-self-aligned contact hole 23 is used in the second embodiment and is the same as the contact hole 9 formed in the high breakdown voltage transistor 6. In the semiconductor device of the second embodiment, the distance between the gate electrodes 5 in the memory cell region 2 is set to be longer than in the first embodiment.

A contact hole 23 is formed in a interlayer insulating film 20 so as to be located between the gate electrodes 5 of the memory cell region 3. The silicon nitride film 19 and the silicon oxide film 18 are removed by the etching process such that the silicon substrate 1 is exposed. The contact hole 23 has a sidewall on which is formed the silicon nitride film 21 serving as the spacer nitride film in the same manner as the contact hole 9. The polycrystalline silicon film 22 serving as an electrode conductor is buried in the contact hole 9.

The fabrication process of the foregoing structure will be described with reference to FIGS. 4A to 4R. The silicon oxide films 10 and 11 are formed as the gate insulating films on the silicon substrate 1, and the gate electrodes 5 and 7 are formed, as shown in FIGS. 4A and 4B. As shown, the distance A between the gate electrodes 5 in the second embodiment is set to be larger than in the first embodiment. Each of the gate electrodes 5 and 7 is formed by stacking, from below, the polycrystalline silicon film 12 serving as a floating gate, the ONO film 13, the polycrystalline silicon film 14 serving as a control gate, the WSi film 15 and the silicon nitride film 16 sequentially.

Subsequently, as shown in FIGS. 4C and 4D, the thin silicon oxide film 17 is formed by thermal oxidation on both sides of the gate electrodes 5 and 7 and the upper surface of the silicon substrate 1. The silicon oxide film 18 is formed on the entire upper surface side of the silicon substrate 1 as shown in FIGS. 4E and 4F. Successively, as shown in FIGS. 4G and 4H, a silicon nitride film 19a for processing the sidewalls. The sidewalls are processed so that spacers are formed on the sidewalls of the gate electrodes 5 and 7 as shown in FIGS. 4I and 4J. Successively, the source-drain region 1a is formed in the active layer of the high breakdown voltage transistor 6.

Next, the silicon nitride film 19 is again formed substantially over the entire upper surface side of the silicon substrate 1 and the interlayer insulating film 20 is then deposited substantially over the entire upper surface side of the silicon substrate 1 so that the gate electrodes 5 and 7 are buried therein, as shown in FIGS. 4K and 4L. Subsequently, the contact holes 23 and 9 are formed in the interlayer insulating film 20 as shown in FIGS. 4M and 4N. The etching progress is stopped when the surface of the silicon nitride film 19 is exposed, as in the first embodiment. Furthermore, the contact hole 23 is open in the region between the gate electrodes 5 in the second embodiment. The second embodiment differs from the first embodiment in this respect.

Subsequently, the silicon nitride film 21 serving as the spacer nitride film is formed as shown in FIGS. 4O and 4P. The silicon nitride film 21 and the silicon oxide film 18 are etched so that the silicon substrate 1 is exposed. In this state, the silicon nitride film 21 remains on the sidewalls of the contact holes 23 and 9 of the interlayer insulating film 20. Successively, the polycrystalline silicon film 22 serving as a buried material and the like are deposited, and the etchback process is carried out so that the structure as shown in FIGS. 3A and 3B is obtained. The processing of the contacts is completed.

As in the first embodiment, the silicon nitride film 21 formed on the sidewalls of the contact holes 23 and 9 has no portion in contact with the silicon substrate 1 and is accordingly formed with the silicon oxide film 18 being interposed between the silicon nitride film 21 and the substrate 1 in the second embodiment. Consequently, stress on the silicon substrate 1 can be relaxed or eased and electron trap of the gate oxide film can be reduced, whereupon a flash memory with high reliability can be achieved.

Furthermore, in the above-described fabrication process, the number of times of the etching process of the silicon nitride films 19a and 19 by the RIE process can be reduced to 2 although the etching process is conventionally carried out three times. Thus, the number of steps can be reduced such that the fabrication process can be shortened and the production cost can be reduced.

The invention should not be limited to the foregoing embodiments and the embodiments may be modified or expanded as follows. The invention should not be limited to the NAND flash memory but may be applied to any structure in which a contact hole is provided in an interlayer insulating film and a spacer insulating film is formed on a sidewall of the contact hole.

The foregoing description and drawings are merely illustrative of the principles of the present invention and are not to be construed in a limiting sense. Various changes and modifications will become apparent to those of ordinary skill in the art. All such changes and modifications are seen to fall within the scope of the invention as defined by the appended claims.

What is claimed is:

1. A semiconductor device comprising:
a semiconductor substrate;
a gate insulating film formed on the semiconductor substrate;
a gate electrode formed on the gate insulating film;
an interlayer insulating film formed so that the gate electrode is buried therein;
a contact hole formed in the interlayer insulating film so as to be adjacent to the gate electrode, the contact hole having a sidewall;
a nitride film for the spacer formed on the sidewall of the contact hole and having a lower end;
an insulating film interposed between the lower end of the spacer nitride film and a surface of the semiconductor substrate; and
a conductor layer for the electrode formed so as to fill the contact hole.

2. The semiconductor device according to claim 1, wherein the contact hole is a self-aligned contact hole having a peripheral edge located on the gate electrode.

3. The semiconductor device according to claim 1, wherein the contact hole has an open end located between the gate electrodes adjacent to the contact hole.

4. The semiconductor device according to claim 1, further comprising a transistor forming a memory cell array, wherein the gate electrodes are formed as gate electrodes of the transistor, and the memory cell array includes a plurality of selective gate electrodes.

5. The semiconductor device according to claim 2, further comprising a transistor forming a memory cell array, wherein the gate electrodes are formed as gate electrodes of the transistor, and the memory cell array includes a plurality of selective gate electrodes.

6. The semiconductor device according to claim 3, further comprising a transistor forming a memory cell array, wherein the gate electrodes are formed as gate electrodes of the transistor, and the memory cell array includes a plurality of selective gate electrodes.

7. A method of fabricating a semiconductor device comprising:
forming a gate electrode on a semiconductor substrate;
forming an insulating film and a nitride film so as both to cover the gate electrode;
forming an interlayer insulating film;
processing the interlayer insulating film by an RIE process, thereby forming a contact hole so that the insulating film and the nitride film remains on a bottom of the contact hole;
forming a nitride film for a spacer in the contact hole;
processing the spacer nitride film, the nitride film and the insulating film by an RIE process so that a surface of the semiconductor device is exposed; and
burying a conductive layer for an electrode in the formed contact hole.

8. The method according to claim 7, further comprising removing the insulating film in a region corresponding to an opening of the contact hole prior to the interlayer insulating film forming step, wherein in the contact hole forming step, the contact hole is formed so that a peripheral edge of the contact hole is located on the gate electrodes.

9. The method according to claim 7, wherein in the contact hole forming step, the contact hole is formed in the interlayer insulating film so as to be located between the gate electrodes adjacent to each other.
